(19) United States
(12) Patent Application Publication
(10) Pub. No.: US 2026/0122824 A1
(43) Pub. Date: Apr. 30, 2026

(54) PROCESSOR INTEGRATED MODULE, SERVER, AND ASSEMBLY METHOD FOR PROCESSOR INTEGRATED MODULE

(71) Applicant: SUZHOU METABRAIN INTELLIGENT TECHNOLOGY CO., LTD., Suzhou, Jiangsu (CN)

(72) Inventor: Yuzhong ZHANG, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 19/469,783

(22) PCT Filed: Dec. 13, 2024
(86) PCT No.: PCT/CN2024/139393

§ 371 Date: Sep. 26, 2025

(30) Foreign Application Priority Data
Mar. 15, 2024 (CN) 202410302149.9

(51) Int. Cl. H05K 7/14; H05K 7/20

(52) U.S. Cl. CPC H05K 7/1487; H05K 7/1439; H05K 7/1489; H05K 7/1492; H05K 7/20409; H05K 7/20736

(57) ABSTRACT

Provided are a processor integrated module, a server, and an assembly method for a processor integrated module. The processor integrated module includes: a frame body; a first limiting member rotatably installed on the frame body, the first limiting member and a second side frame limit a processor assembly in a first direction; and a second limiting member rotatably installed on the frame body, the second limiting member and a back plate limit the processor assembly in a second direction, and the second direction is perpendicular to the first direction and parallel to a direction in which the processor assembly enters and exits a chamber.

### CROSS-REFERENCE TO RELATED APPLICATION

The present disclosure claims the priority to Chinese Patent Application No. 202410302149.9, filed with the China National Intellectual Property Administration (CNIPA) on Mar. 15, 2024, and entitled “Processor Integrated Module, Server, and Assembly Method for Processor Integrated Module”, which is herein incorporated by reference in its entirety.

### TECHNICAL FIELD

The present disclosure relates to the technical field of server devices, and in particular to a processor integrated module, a server, and an assembly method for a processor integrated module.

### BACKGROUND

Currently, in a server chassis, a fan module is typically arranged between a hard disk module and a front-row central processing unit (CPU). As a server is required to support increasingly higher power, the CPU needs to dissipate more heat, resulting in higher intake air temperatures for a graphics processing unit (GPU). Meanwhile, since a GPU module is close to a rear window of the chassis and is far from the fan module at the front of the chassis, the GPU module experiences a low air pressure, resulting in even worse heat dissipation conditions for the GPU module.

In the related art, to improve a heat dissipation effect of the GPU module, the higher air pressure is provided typically through a method for increasing the rotational speed of the fan module. However, the higher rotational speed results in increased noise, which not only affects the use experience of a user but also easily causes the deviation of a hard disk head within the hard disk module, leading to reduced read-write efficiency, writing errors, sector failures, and even hard disk failures. Alternatively, in the related art, to reduce noise, methods such as applying acoustic absorption cotton along a path between the hard disk module and the fan module inside the chassis, or adding honeycomb nets at an air inlet of the fan module are adopted. However, the foregoing operations may lead to increased costs and have insignificant effects on noise reduction.

Therefore, how to meet heat dissipation requirements of the GPU module while reducing noise is a technical problem that needs to be solved by those skilled in the art.

### SUMMARY

The objective of the present disclosure is to provide a processor integrated module, a server, and an assembly method for a processor integrated module, which may effectively reduce the noise and vibration impact generated by a heat dissipation member, and also meet heat dissipation requirements for a processor assembly, achieving firm limitation of the processor assembly.

In order to achieve the above objective, the present disclosure provides following technical solutions:
Some embodiments of the present disclosure provide a processor integrated module, including: a frame body, the frame body includes a back plate, and a first side frame and a second side frame which are opposite to each other, the back plate, the first side frame, and the second side frame enclose to form a chamber, a support portion for accommodating a processor assembly is disposed in the chamber of the frame body, and the processor assembly is provided with a heat dissipation member; a first limiting member, the first limiting member is rotatably installed on the frame body, and the first limiting member and the second side frame limit the processor assembly in a first direction; and a second limiting member, the second limiting member is rotatably installed on the frame body, and the second limiting member and the back plate limit the processor assembly in a second direction, and the second direction is perpendicular to the first direction and parallel to a direction in which the processor assembly enters and exits the chamber.

In some embodiments, the processor integrated module further includes: a first locking member, the first locking member is configured for locking or unlocking the first limiting member and the first side frame, one side of the first limiting member is hingedly connected to the first side frame or the back plate, and the other side thereof is connected to the first locking member, the first locking member is movably installed on the first side frame, and in response to the first locking member being unlocked, the first limiting member swings relative to the first side frame; a second locking member, the second locking member is configured for locking or unlocking the second limiting member and the second side frame, one side of the second limiting member is hingedly connected to the second side frame or the back plate, and the other side thereof is connected to the second locking member, the second locking member is movably installed on the second side frame, and in response to the second locking member being unlocked, the second limiting member swings relative to the second side frame.

In some embodiments, the first locking member is a threaded fastener, the first side frame is provided with a threaded hole, and the threaded fastener is assembled into the threaded hole and is in fastened connection. The second locking member includes a slider and a locking edge, the locking edge is located at a movable end of the second limiting member, and the slider is disposed on the second side frame, in response to the second limiting member tightly fitting against the second side frame, the slider slides to the locking edge for snap fit to lock a position of the second limiting member.

In some embodiments, the support portion includes a first slideway located on an inner wall of the first side frame and a second slideway located on an inner wall of the second side frame, a plurality of first slideways and a plurality of second slideways are provided, the first slideway is arranged parallel to the second slideway, two ends of the processor assembly in the first direction slide along the first slideway and the second slideway respectively to enter or exit the chamber.

In some embodiments, a movable end of the first limiting member is further provided with a limiting edge, the limiting edge is internally provided with a limiting slot, the limiting slot is configured for accommodating a corner of the processor assembly, and limits the processor assembly in the first direction and the second direction.

In some embodiments, a notch portion is disposed on one side, away from the back plate, of the first side frame, a rotation of the first limiting member moves the limiting edge to the notch portion, and the limiting slot in the limiting edge communicates with the first slideway.

In some embodiments, the processor integrated module further includes at least two handles for gripping, the frame body is provided with grooves, and the at least two handles are arc-shaped with rotating shafts at two ends, and the at least two handles are rotatably installed in the grooves through the rotating shafts and are able to extend out of the grooves.

In some embodiments, the processor integrated module further includes: a first rotating shaft, one side of the first limiting member is rotatably connected to the first rotating shaft, the other side thereof rotates relative to the first rotating shaft and opens towards an outer side of the first side frame, and one side, away from the first rotating shaft, of the first limiting member is detachably connected to the first side frame; a second rotating shaft, one side of the second limiting member is rotatably connected to the second rotating shaft, the other side thereof rotates relative to the second rotating shaft and opens towards an outer side of the second side frame, and one side, away from the second rotating shaft, of the second limiting member is detachably connected to the second side frame; the frame body further includes a top plate perpendicular to the back plate, the first side frame is connected to one end of the top plate and one end of the back plate, and the second side frame is connected to the other end of the top plate and the other end of the back plate; the first rotating shaft is located on a connecting edge between the first side frame and the top plate, or on a connecting edge between the first side frame and the back plate, and an extension direction of the first rotating shaft is parallel to a plane where the first side frame is located; the second rotating shaft is located at a corner, away from the top plate and the back plate, of the second side frame, and an extension direction of the second rotating shaft is perpendicular to a plane where the second side frame is located; the first rotating shaft is further provided with a first angle limiting portion configured for limiting a maximum rotation angle of the first limiting member, and the second rotating shaft is further provided with a second angle limiting portion configured for limiting a maximum rotation angle of the second limiting member.

In some embodiments, the processor integrated module further includes a third locking member, a locking edge is disposed on one side, away from the first side frame, of the first limiting member, the locking edge is suspended over a surface of an air guide hood of the server or inserted into a housing of the air guide hood, the third locking member is disposed on the locking edge and is in fastened connection to the air guide hood.

In some embodiments, a plurality of reinforcing ribs are disposed between the locking edge and the first limiting member, and a ventilation channel is disposed between adjacent reinforcing ribs of the plurality of reinforcing ribs, and allows air to flow from an outer side of the first limiting member into the chamber of the frame body.

In some embodiments, the processor assembly includes: a processor body; a heat dissipation member, the heat dissipation member is configured for dissipating heat for the processor body; and a heat dissipation mounting bracket, the heat dissipation mounting bracket is disposed at one end of the processor body in the first direction, and the heat dissipation member is detachably disposed on the heat dissipation mounting bracket.

In some embodiments, the heat dissipation mounting bracket is installed at a first end of the processor body in the first direction, and the heat dissipation mounting bracket is connected to the first side frame, a second end of the processor body in the first direction is connected to the second side frame, and the first side frame is provided with a plurality of ventilation slots.

In some embodiments, the heat dissipation mounting bracket includes an extension member and a heat dissipation limiting member, and a heat dissipation space for accommodating the heat dissipation member is disposed between the heat dissipation limiting member and the extension member; the extension member is connected to the processor body, and the heat dissipation limiting member is detachably connected to the extension member; an edge, away from the processor body, of the extension member is provided with a support edge, and the support edge is fittingly connected to a support portion in the frame body.

In some embodiments, two ends of the heat dissipation member are provided with a heat dissipation fixing hole, and both the extension member and the heat dissipation limiting member are provided with a mounting bracket fixing hole. The heat dissipation fixing hole and the mounting bracket fixing hole are detachably connected through a heat dissipation fixing member.

In some embodiments, the processor integrated module further includes a shock-absorbing pad, the heat dissipation fixing member includes a fixing member body, a first fixing post, and a second fixing post, the first fixing post is connected to the heat dissipation fixing hole by interference fit, the shock-absorbing pad is wrapped around the fixing member body and the second fixing post, and a position, close the second fixing post, of the shock-absorbing pad is connected to the mounting bracket fixing hole by interference fit.

In some embodiments, the processor integrated module further includes a position detecting member, the position detecting member is configured for detecting whether the processor assembly is installed in the chamber in place; an alarm member, the alarm member is connected to the position detecting member, and is configured for emitting an alarm signal in response to the processor assembly being installed in place; a power mechanism, the power mechanism is configured for driving a movement of the first limiting member and the second limiting member; and a controller, the controller is connected to the alarm member, and is configured for controlling a rotation of the first limiting member to fit against the first side frame and a rotation of the second limiting member to fit against the second side frame in response to receiving the alarm signal.

Some other embodiments of the present disclosure further provide a server, including the foregoing processor integrated module.

Still some other embodiments of the present disclosure further provide an assembly method for a processor integrated module, including the following steps: step S1: rotating a first limiting member and a second limiting member to move the first limiting member and the second limiting member away from a chamber; step S2: placing a processor assembly into the chamber of a frame body; and step S3: after installing the processor assembly in place, locking the first limiting member onto a first side frame, thereby limiting the processor assembly by the first limiting member and the second side frame in the first direction; and locking the second limiting member onto a second side frame, thereby limiting the processor assembly by the second limiting member and the back plate in the second direction.

The technical solution of the present disclosure has the beneficial effects: through the arrangement of the frame body in the provided processor integrated module, the back plate, the first side frame, and the second side frame enclose to form the chamber for accommodating the processor assembly, and moreover, to facilitate the placement of the processor assembly, the support portion is disposed in the chamber of the frame body, when the processor assembly needs to be installed, the processor assembly is directly placed on the support portion, or pushed into the chamber along the support portion, and when the processor assembly needs to be removed, a reverse operation is preformed; to achieve a heat dissipation effect for the processor assembly, the heat dissipation member is disposed on the processor assembly, the heat dissipation member is used to directly cool the processor assembly, and a cooling purpose for the processor assembly may be achieved without the need to increase a rotational speed of a fan module, since the heat dissipation member is directly installed on the processor assembly, the heat dissipation effect of the heat dissipation member on the processor assembly is more direct and effective, heat dissipation requirements of the processor assembly may be met without the high rotational speed and air pressure of the heat dissipation member, therefore, by arranging the heat dissipation member on the processor assembly, the impact of high noise on a user may be effectively avoided.

In the technical solution of the present disclosure, through the arrangement of the first limiting member and the second limiting member, the processor assembly is limited in the first direction by the first limiting member and the second side frame, and the processor assembly is limited in the second direction by the second limiting member and the back plate, thereby achieving all-round limitation of the processor assembly in different directions and reducing the noise and vibration impact caused by the installation of the heat dissipation member; meanwhile, in a process of locking the first limiting member and the first side frame, the first limiting member may press the processor assembly against the second side frame, thereby achieving limitation and fixation of the processor assembly in the first direction.

Similarly, in a process of locking the second limiting member and the second side frame, the second limiting member may press the processor assembly against the back plate or against the support portion, thereby achieving limitation and fixation of the processor assembly in the second direction, effectively reducing the vibration and noise problems caused by the installation of the heat dissipation member, and meanwhile reducing the risk of the processor assembly shaking or falling within the chamber.

According to the processor integrated module provided in the present disclosure, by installing the heat dissipation member on the processor assembly, an air intake pressure for the processor assembly is increased in a more targeted manner, thereby improving a heat dissipation status of the processor assembly, there is no need to overall increase the rotational speed of the fan module at the front inside a server chassis, thereby reducing the impact of noise at the high rotational speed of the fan on transmission performance of a hard disk, reducing the use of noise reduction measures, and meanwhile partially reducing the impact of a noise environment on operation and maintenance personnel, while improving heat dissipation performance of the processor assembly, the experience of the user in noise perception is not increased, and meanwhile the vibration generated by the newly added heat dissipation member is reduced, thereby reducing the impact on the entire server.

The server provided in the present disclosure is provided with the foregoing processor integrated module, since the processor integrated module has the technical effects described above, the server provided with the processor integrated module should also have corresponding technical effects.

According to the assembly method for a processor integrated module provided in the present disclosure, the first limiting member and the second limiting member are rotated to make way for the processor assembly, thereby facilitating the arrangement of the processor assembly into the chamber of the frame body, after the processor assembly is installed in place, the first limiting member is rotated to fasten one end of the processor assembly in the first direction, thereby limiting the processor assembly in the first direction, the second limiting member is rotated to fasten one side of the processor assembly in the second direction, thereby limiting the processor assembly in the second direction, and then, the first limiting member is locked onto the first side frame, and the second limiting member is locked onto the second side frame, thereby completing the assembly process of the processor integrated module, achieving multi-angle fixation of the processor assembly, thus effectively reducing the noise and vibration impact caused by the arrangement of the heat dissipation member on the processor assembly, and minimizing the impact on use experience of the user while meeting the heat dissipation requirements of the processor assembly.

### BRIEF DESCRIPTION OF THE DRAWINGS

In order to more clearly describe the technical solutions in the embodiments of the present disclosure or in the related art, the accompanying drawings for describing the embodiments or the related art will be briefly described below. Apparently, the accompanying drawings in the description below show merely some embodiments in the present disclosure, and those of ordinary skill in the art may still derive other accompanying drawings from these accompanying drawings without creative efforts.

FIG. 1 is a schematic structural diagram of an embodiment of a processor integrated module according to the present disclosure;

FIG. 2 is an exploded view of the processor integrated module shown in FIG. 1;

FIG. 3 is a schematic diagram of a bracket module in a processor integrated module according to the present disclosure;

FIG. 4 is an enlarged schematic diagram of a structure A in the bracket module shown in FIG. 3;

FIG. 5 is an enlarged schematic diagram of a structure B in the bracket module shown in FIG. 3;

FIG. 6 is a schematic diagram of a bracket module from another perspective in a processor integrated module according to the present disclosure;

FIG. 7 is an enlarged schematic diagram of a structure C in the bracket module shown in FIG. 6;

FIG. 8 is a schematic structural diagram of a processor assembly in a processor integrated module according to the present disclosure;

FIG. 9 is an exploded view of the processor assembly shown in FIG. 8;

FIG. 10 is a schematic structural diagram of a heat dissipation member in the processor assembly shown in FIG. 8;

FIG. 11 is a schematic structural diagram of an extension member in the processor assembly shown in FIG. 8;

FIG. 12 is a schematic structural diagram of a heat dissipation limiting member in the processor assembly shown in FIG. 8;

FIG. 13 is a schematic structural diagram of a heat dissipation fixing member in the processor assembly shown in FIG. 8;

FIG. 14 is a sectional view of the heat dissipation fixing member shown in FIG. 13;

FIG. 15 is a schematic diagram of a server layout according to the present disclosure;

FIG. 16 is a schematic diagram of a server with a cover opened according to the present disclosure;

FIG. 17 is a top view of a server with a cover opened according to the present disclosure; and

FIG. 18 is a flowchart of an assembly method for a processor integrated module of an embodiment according to the present disclosure.

### REFERENCE NUMERALS

10—processor integrated module; 20—hard disk module; 30—fan module; 40—front air guide hood; 50—rear air guide hood; 60—chassis base; 70—power module; 80—chassis upper cover; 90—CPU; 1—frame body; 11—back plate; 12—first side frame; 121—first slideway; 122—notch portion; 13—second side frame; 131—second slideway; 14—top plate; 141—handle; 15—first locking member; 16—second locking member; 161—slider; 162—locking edge; 17—first rotating shaft; 18—second rotating shaft; 19—third locking member; 2—first limiting member; 21—limiting edge; 211—limiting slot; 22—locking edge; 23—reinforcing rib; 3—second limiting member; 4—processor assembly; 41—processor body; 42—heat dissipation member; 421—heat dissipation fixing hole; 43—heat dissipation mounting bracket; 431—extension member; 4311—support edge; 4312—assembly hole; 432—heat dissipation limiting member; 4321—threaded fastener; 433—heat dissipation fixing member; 4331—fixing member body; 4332—first fixing post; 4333—second fixing post; 434—shock-absorbing pad; 435—mounting bracket fixing hole; and 5—riser card.

### DETAILED DESCRIPTION OF THE EMBODIMENTS

A core of the present disclosure is to provide a processor integrated module, a server, and an assembly method for a processor integrated module, which may reduce noise and mitigate the impact generated by vibration.

Technical solutions in embodiments of the present disclosure are clearly and completely described below in combination with accompanying drawings in the embodiments of the present disclosure, and it is apparent that the described embodiments are merely a part rather all of the embodiments of the present disclosure. All other embodiments obtained by those of ordinary skill in art without creative labor based on the embodiments of the present disclosure shall fall within the scope of protection of the present disclosure.

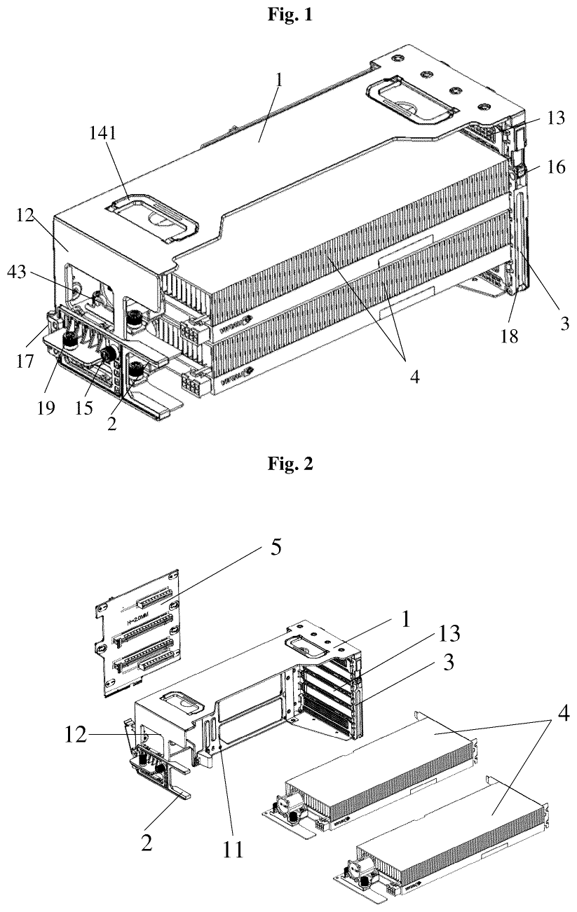

Referring to FIGS. 1-2, in the embodiment, a processor integrated module 10 includes a frame body 1, the frame body 1 includes a back plate 11, and a first side frame 12 and a second side frame 13 which are opposite to each other, the back plate 11, the first side frame 12, and the second side frame 13 enclose to form a chamber, a support portion for accommodating a processor assembly 4 is disposed in the chamber of the frame body 1, and the processor assembly 4 is provided with a heat dissipation member 42; a first limiting member 2, the first limiting member 2 is rotatably installed on the frame body 1, and the first limiting member 2 and the second side frame 13 limit the processor assembly 4 in a first direction; and a second limiting member 3, the second limiting member 3 is rotatably installed on the frame body 1, and the second limiting member 3 and the back plate 11 limit the processor assembly 4 in a second direction, and the second direction is perpendicular to the first direction and parallel to a direction in which the processor assembly 4 enters and exits the chamber.

The processor integrated module 10 includes a bracket module. The bracket module includes the frame body 1, the first limiting member 2, and the second limiting member 3. Through the arrangement of the frame body 1, the first side frame 12 and the second side frame 13 are respectively located at two ends of the back plate 11 in the first direction. The back plate 11, the first side frame 12, and the second side frame 13 enclose to form the chamber for accommodating the processor assembly 4. Moreover, to facilitate the placement of the processor assembly 4, the support portion is disposed in the chamber of the frame body 1. When the processor assembly 4 needs to be installed, the processor assembly 4 is directly placed on the support portion or pushed into the chamber along the support portion. When the processor assembly 4 needs to be removed, a reverse operation may be performed. Specifically, the support portion is disposed on the first side frame 12 and the second side frame 13, specifically on the opposite sides of the first side frame 12 and the second side frame 13, for supporting two ends of the processor assembly 4 in the first direction. Due to a large size of the processor assembly 4 in the first direction, supporting the two ends of the processor assembly 4 in the first direction may, on the one hand, improve the installation efficiency of the processor assembly 4, and on the other hand, ensure the stability of the processor assembly 4 in a length direction. To achieve a heat dissipation effect for the processor assembly 4, the heat dissipation member 42 is disposed on the processor assembly 4. The heat dissipation member 42 is used to directly cool the processor assembly 4, and a cooling purpose for the processor assembly 4 may be achieved without the need to increase a rotational speed of the fan module 30. Since the heat dissipation member 42 is directly installed on the processor assembly 4, the heat dissipation effect of the heat dissipation member 42 on the processor assembly 4 is more direct and effective. Heat dissipation requirements of the processor assembly 4 may be met without the high rotational speed and air pressure of the heat dissipation member 42. Therefore, by arranging the heat dissipation member 42 on the processor assembly 4, the impact of high noise on a user may be effectively avoided.

In the embodiment of the present disclosure, through the arrangement of the first limiting member 2 and the second limiting member 3, the processor assembly 4 is limited in the first direction by the first limiting member 2 and the second side frame 13, and the processor assembly 4 is limited in the second direction by the second limiting member 3 and the back plate 11, thereby achieving all-round limitation of the processor assembly 4 in different directions and reducing the noise and vibration impact caused by the installation of the heat dissipation member 42. Meanwhile, in a process of locking the first limiting member 2 and the first side frame 12, the first limiting member 2 may press the processor assembly 4 against the second side frame 13, thereby achieving limitation and fixation of the processor assembly 4 in the first direction.

Similarly, in a process of locking the second limiting member 3 and the second side frame 13, the second limiting member 3 may press the processor assembly 4 against the back plate 11 or against the support portion, thereby achieving limitation and fixation of the processor assembly 4 in the second direction, effectively reducing the vibration and noise problems caused by the installation of the heat dissipation member 42, and meanwhile reducing the risk of the processor assembly 4 shaking or falling within the chamber.

According to the processor integrated module 10 provided in the present disclosure, by installing the heat dissipation member 42 on the processor assembly 4, an air intake pressure for the processor assembly 4 is increased in a more targeted manner, thereby improving a heat dissipation status of the processor assembly 4. There is no need to overall increase the rotational speed of the fan module 30 at the front inside a server chassis, thereby reducing the impact of noise at the high rotational speed of a fan on transmission performance of a hard disk, reducing the use of noise reduction measures, and meanwhile partially reducing the impact of a noise environment on operation and maintenance personnel. While improving heat dissipation performance of the processor assembly 4, the experience of the user in noise perception is not increased, and meanwhile the vibration generated by the newly added heat dissipation member 42 is reduced, thereby reducing the impact on the entire server.

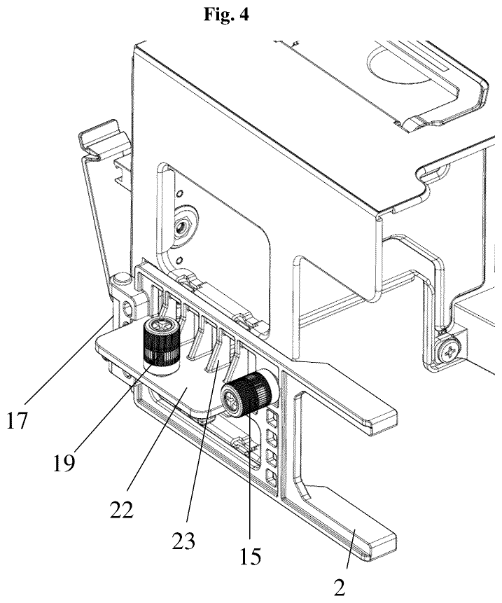

In some embodiments, referring to FIG. 4, the processor integrated module 10 further includes a first locking member 15, and the first locking member 15 is configured for locking or unlocking the first limiting member 2 and the first side frame 12. One side of the first limiting member 2 is hingedly connected to the first side frame 12 or the back plate 11, and the other side of the first limiting member 2 is connected to the first locking member 15. The first locking member 15 is movably installed on the first side frame 12, and when the first locking member 15 is unlocked, the first limiting member 2 may swing relative to the first side frame 12. Specifically, the function of the first locking member 15 is to fix a relative position of the first limiting member 2 and the first side frame 12, thereby fastening the processor assembly 4 in the first direction. In some other embodiments, the first locking member 15 may not be disposed. For example, an elastic structure may be disposed on the first limiting member 2. After the first limiting member 2 is opened and the installation of the processor assembly 4 is completed, the first limiting member 2 may be driven to be kept in a locked state through an elastic reset manner.

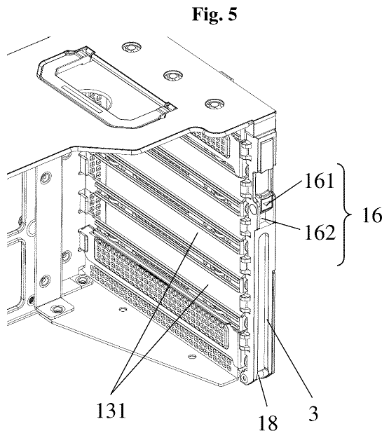

In some embodiments, referring to FIG. 5, the processor integrated module 10 further includes a second locking member 16, and the second locking member 16 is configured for locking or unlocking the second limiting member 3 and the second side frame 13. One side of the second limiting member 3 is hingedly connected to the second side frame 13 or the back plate 11, and the other side of the second limiting member 3 is connected to the second locking member 16. The second locking member 16 is movably installed on the second side frame 13, and when the second locking member 16 is unlocked, the second limiting member 3 may swing relative to the second side frame 13. Similarly, the function of the second locking member 16 is to fix a relative position of the second limiting member 3 and the second side frame 13, thereby fastening the processor assembly 4 in the second direction. In some other embodiments, the second locking member 16 may not be disposed. For example, an elastic structure may be disposed on the second limiting member 3. After the second limiting member 3 is opened and the installation of the processor assembly 4 is completed, the second limiting member 3 may be driven to be kept in the locked state through the elastic reset manner.

In some embodiments, referring to FIG. 4, the first locking member 15 is a threaded fastener 4321. The first side frame 12 is provided with a threaded hole, and the threaded fastener 4321 may be assembled into the threaded hole and be in fastened connection. Specifically, when the processor assembly 4 needs to be installed, the threaded fastener 4321 is loosened. After the threaded fastener 4321 is separated from the first side frame 12, the first limiting member 2 may be rotated. After the installation of the processor assembly 4 is completed, the first limiting member 2 is reversely rotated until the first limiting member 2 fits against the first side frame 12. In this case, the threaded fastener 4321 is tightened into the threaded hole of the first side frame 12. Specifically, before the first locking member 15 takes effect, the first limiting member 2 makes contact with the processor assembly 4. During a locking process of the first locking member 15, further pressure may be applied to the first limiting member 2, thereby pressing the processor assembly 4 to ensure the stability of the processor assembly 4 and reduce noise and vibration.

In some embodiments, referring to FIG. 5, the second locking member 16 includes a slider 161 and a locking edge 162. The locking edge 162 is located at a movable end of the second limiting member 3, and the slider 161 is disposed on the second side frame 13. When the second limiting member 3 tightly fits against the second side frame 13, the slider 161 may slide to the locking edge 162 for snap fit to lock a position of the second limiting member 3. Specifically, when the processor assembly 4 needs to be installed, the slider 161 is pushed. After the slider 161 is separated from the second limiting member 3, the second limiting member 3 may be rotated. After the installation of the processor assembly 4 is completed, the second limiting member 3 is reversely rotated until the second limiting member 3 fits against the second side frame 13. In this case, the slider 161 slides back to a position of the locking edge 162 again. Specifically, before the second locking member 16 takes effect, the second limiting member 3 makes contact with the processor assembly 4. During a locking process of the second locking member 16, further pressure may be applied to the second limiting member 3, thereby pressing the processor assembly 4 to ensure the stability of the processor assembly 4 and reduce noise and vibration.

In some embodiments, the first limiting member 2 is provided with a first magnetic locking member, and the first side frame 12 is provided with a first magnetic member, and the first magnetic member may attract the first magnetic locking member. When the first limiting member 2 is opened, magnetic force between the first magnetic member and the first magnetic locking member weakens. When the first limiting member 2 needs to be closed, under the attraction of the first magnetic member and the first magnetic locking member, the first limiting member 2 may quickly fit against the first side frame 12 to achieve locking, thereby effectively improving the assembly efficiency. In the embodiment, the first magnetic locking member may serve as both a power source for rotating the first limiting member 2 and a locking member. Due to a limited locking effect of magnetic attraction, in a case of cooperation with the first magnetic locking member, structural locking may be performed in cooperation with the first locking member 15, such as the threaded fastener 4321, thereby further improving the stability of the processor assembly 4 in the first direction.

In some embodiments, the second limiting member 3 is provided with a second magnetic locking member, and the second side frame 13 is provided with a second magnetic member, and the second magnetic member may attract the second magnetic locking member. When the second limiting member 3 is opened, magnetic force between the second magnetic member and the second magnetic locking member weakens. When the second limiting member 3 needs to be closed, under the attraction of the second magnetic member and the second magnetic locking member, the second limiting member 3 may quickly fit against the second side frame 13 to achieve locking, thereby effectively improving the assembly efficiency. In the embodiment, the second magnetic locking member may serve as both a power source for rotating the second limiting member 3 and a locking member. Due to a limited locking effect of magnetic attraction, in a case of cooperation with the second magnetic locking member, structural locking may be performed in cooperation with the second locking member 16, such as the slider 161 and the locking edge 162, thereby further improving the stability of the processor assembly 4 in the second direction.

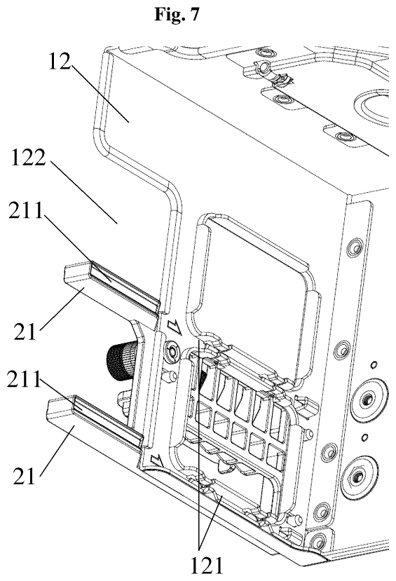

In some embodiments, referring to FIG. 5 and FIG. 7, the support portion includes a first slideway 121 located on an inner wall of the first side frame 12 and a second slideway 131 located on an inner wall of the second side frame 13. The first slideway 121 is arranged parallel to the second slideway 131. The two ends of the processor assembly 4 in the first direction slide along the first slideway 121 and the second slideway 131 respectively to enter or exit the chamber. Specifically, the arrangement of the first slideway 121 and the second slideway 131 may facilitate the processor assembly 4 to enter or exit, resulting in high assembly efficiency. Specifically, a plurality of first slideways 121 and a plurality of second slideways 131 are provided, with the same quantity of each, and the plurality of first slideways 121 and the plurality of second slideways 131 are in one-to-one correspondence. The number of the first slideway 121 and the second slideway 131 determines the number of the processor assembly 4 that may be placed, which may be set according to requirements.

In some embodiments, referring to FIG. 7, a movable end of the first limiting member 2 is further provided with a limiting edge 21. The limiting edge 21 is internally provided with a limiting slot 211, the limiting slot 211 is configured for accommodating a corner of the processor assembly 4, thereby limiting the processor assembly 4 in the first direction and the second direction. The limiting slot 211 may limit the corner of the processor assembly 4, such as a bracket of the processor assembly 4, in a vertical direction, as well as limit an outer side of the processor assembly 4 in the second direction. With this arrangement, even if a length of the processor assembly 4 in the first direction is large, the limiting edge 21 and the limiting slot 211 may prevent one end, close the first side frame 12, of the processor assembly 4 from disengaging in the second direction, thereby further ensuring the limitation of the processor assembly 4 at various positions. Specifically, the number of the limiting edges 21 is the same as the number of the first slideways 121. The number of the limiting edge 21 is the same as the number of the first slideway 121, and the limiting edge 21 and the first slideway 121 are in one-to-one correspondence, thereby achieving limitation of each processor assembly 4.

In some embodiments, referring to FIG. 7, a notch portion 122 is disposed on one side, away from the back plate 11, of the first side frame 12. A rotation of the first limiting member 2 may move the limiting edges 21 to the notch portion 122, such that the limiting slot 211 in the limiting edge 21 communicates with the first slideway 121. Specifically, when the limiting slot 211 in the limiting slot communicates with the first slideway 121, the first limiting member 2 may be locked with the first side frame 12. The arrangement of the notch portion 122 may reduce an area of the first side frame 12, and the notch portion 122 may also achieve a ventilation effect, thereby facilitating heat dissipation of the processor assembly 4.

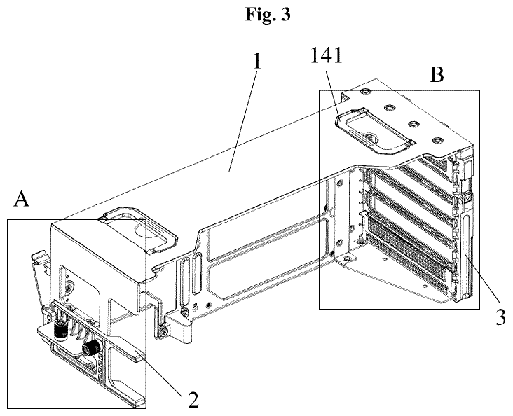

In some embodiments, referring to FIG. 3, the processor integrated module 10 further includes at least two handles 141 for gripping, and the at least two handles 141 are configured for lifting, pulling, inserting, and removing the entire processor integrated module 10. The frame body 1 is provided with grooves, and the at least two handles 141 are arc-shaped with rotating shafts at two ends. The at least two handles 141 are rotatably installed in the grooves through the rotating shafts and may extend out of the grooves. Specifically, when in use, the handles 141 are rotated to be perpendicular to the grooves, and when not in use, the handles 141 are placed inside the grooves. In an embodiment, the handles 141 are provided with anti-slip portions to facilitate gripping by the user and increase friction force.

In some embodiments, referring to FIGS. 4-5, the processor integrated module 10 further includes: a first rotating shaft 17, one side of the first limiting member 2 is rotatably connected to the first rotating shaft 17, the other side of the first limiting member 2 may rotate relative to the first rotating shaft 17 and open towards an outer side of the first side frame 12, and one side, away from the first rotating shaft 17, of the first limiting member 2 is detachably connected to the first side frame 12, thereby facilitating the opening or closing of the first limiting member 2; a second rotating shaft 18, one side of the second limiting member 3 is rotatably connected to the second rotating shaft 18, the other side of the second limiting member 3 may rotate relative to the second rotating shaft 18 and open towards an outer side of the second side frame 13, and one side, away from the second rotating shaft 18, of the second limiting member 3 is detachably connected to the second side frame 13, thereby facilitating the opening and closing of the second limiting member 3.

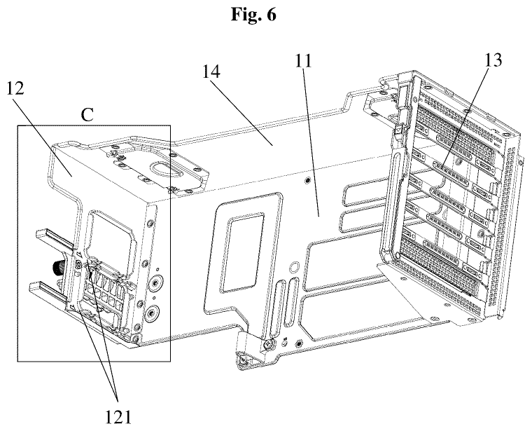

In some embodiments, referring to FIG. 6, the frame body 1 further includes a top plate 14 perpendicular to the back plate 11. The first side frame 12 is connected to one end of the top plate 14 and one end of the back plate 11, and the second side frame 13 is connected to the other end of the top plate 14 and the other end of the back plate 11. The first rotating shaft 17 is located on a connecting edge between the first side frame 12 and the top plate 14, or on a connecting edge between the first side frame 12 and the back plate 11, and an extension direction of the first rotating shaft 17 is parallel to a plane where the first side frame 12 is located. The second rotating shaft 18 is located at a corner, away from the top plate 14 and the back plate 11, of the second side frame 13, and an extension direction of the second rotating shaft 18 is perpendicular to a plane where the second side frame 13 is located. Specifically, the first rotating shaft 17 is located on the connecting edge between the first side frame 12 and the back plate 11, and through the arrangement, a rotation direction of the first limiting member 2 is parallel to an extension direction of the processor assembly 4, thereby facilitating the insertion of the limiting slot 211 in the limiting edge 21 of the first limiting member 2 into the corner of the processor assembly 4 and facilitating assembly.

In some embodiments, the first rotating shaft 17 is further provided with a first angle limiting portion configured for limiting a maximum rotation angle of the first limiting member 2, and the second rotating shaft 18 is further provided with a second angle limiting portion configured for limiting a maximum rotation angle of the second limiting member 3. Specifically, the first angle limiting portion and/or the second angle limiting portion may be a limiting plate tilted at a certain angle or a limiting block installed on the first rotating shaft 17 or the second rotating shaft 18. Any method capable of limiting an angle of the first rotating shaft 17 or the second rotating shaft 18 is acceptable. This arrangement is intended to avoid the excessive rotation angle of the first limiting member 2 and the second limiting member 3, which may lead to interference of the first limiting member 2 and the second limiting member 3 with other structures, while also saving time when the first limiting member 2 and the second limiting member 3 are closed, and thus improving the assembly efficiency.

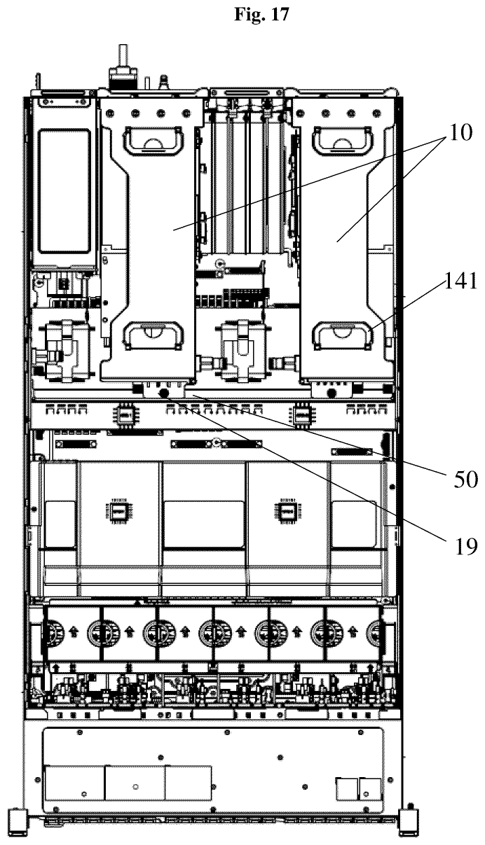

In some embodiments, referring to FIG. 4 and FIG. 17, the processor integrated module 10 further includes a third locking member 19. A locking edge 22 is disposed on one side, away from the first side frame 12, of the first limiting member 2. The locking edge 22 may be suspended over a surface of an air guide hood of the server or inserted into a housing of the air guide hood for convenient fixation with other structures. The third locking member 19 is disposed on the locking edge 22 and may be in fastened connection to the air guide hood. Specifically, in an embodiment, the third locking member 19 is a thumb screw, and the air guide hood is provided with a threaded hole or nut. Through the arrangement of the third locking member 19, the frame body 1, after the installation of the processor assembly 4 is completed, may be assembled onto the air guide hood, thereby achieving the assembly of the processor integrated module 10 with other structures in the server and further reducing noise and vibration impact caused by the heat dissipation member 42.

In some embodiments, referring to FIG. 4, a plurality of reinforcing ribs 23 are disposed between the locking edge 22 and the first limiting member 2, and a ventilation channel is disposed between adjacent reinforcing ribs 23 to allow air to flow from an outer side of the first limiting member 2 into the chamber of the frame body 1. Specifically, the plurality of reinforcing ribs 23 should be parallel to the first direction, such that the ventilation channel between the adjacent reinforcing ribs 23 is parallel to an airflow direction, thereby reducing airflow obstruction while ensuring the strength of the locking edge 22, and thus ensuring the installation firmness of the processor integrated module 10.

In some embodiments, referring to FIG. 2, the processor integrated module 10 further includes a riser card 5. The riser card 5 is fixed to the frame body 1 through screws and is connected to the processor assembly 4 for data transmission. The frame body 1 is further provided with cable clips for fixing transmission cables.

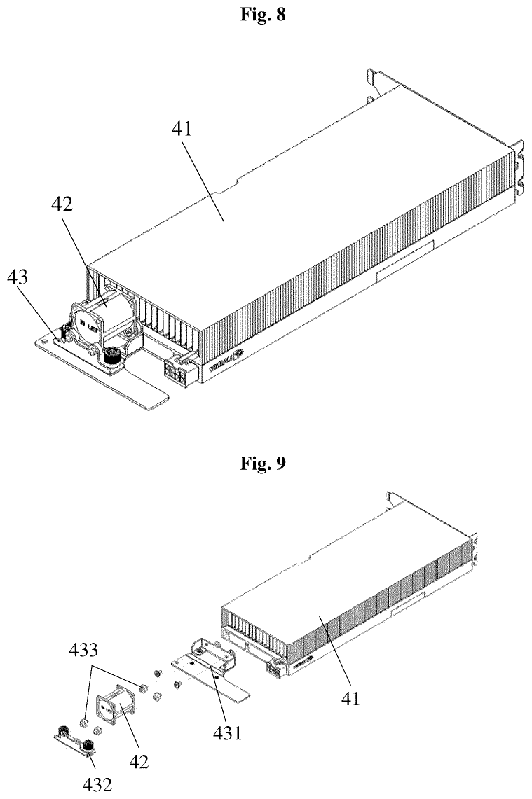

In some embodiments, referring to FIGS. 8-9, the processor assembly 4 includes: a processor body 41; the heat dissipation member 42, the heat dissipation member 42 is configured for dissipating heat for the processor body 41; and a heat dissipation mounting bracket 43. The heat dissipation mounting bracket 43 is disposed at one end of the processor body 41 in the first direction, the heat dissipation member 42 is detachably disposed on the heat dissipation mounting bracket 43, and the heat dissipation member 42 and the heat dissipation mounting bracket 43 may enter or exit the chamber with the processor body 41.

Specifically, the processor body 41 may be a graphics processing unit or another processor, as long as the processor may perform module integration. In an embodiment, the heat dissipation member 42 is a dedicated fan for the processor, and certainly, may also be another heat dissipation member 42 that may generate airflow. The heat dissipation mounting bracket 43 not only has the function of fixing the heat dissipation member 42 but also functions as a slide rail for cooperative connection with the support portion inside the frame body 1.

In some embodiments, referring to FIGS. 8-9, the heat dissipation mounting bracket 43 is installed at a first end of the processor body 41 in the first direction, and the heat dissipation mounting bracket 43 is connected to the first side frame 12. A second end of the processor body 41 in the first direction is connected to the second side frame 13. The first side frame 12 is provided with a plurality of ventilation slots. Through the arrangement of the plurality of ventilation slots, the airflow efficiency may be ensured, the airflow obstruction is reduced, and the heat dissipation effect of the processor body 41 is ensured. It should be noted that the first side frame 12 should be positioned close to the fan module 30, meaning that an airflow direction of the heat dissipation member 42 is the same as that of the fan module 30 to ensure a cooling effect.

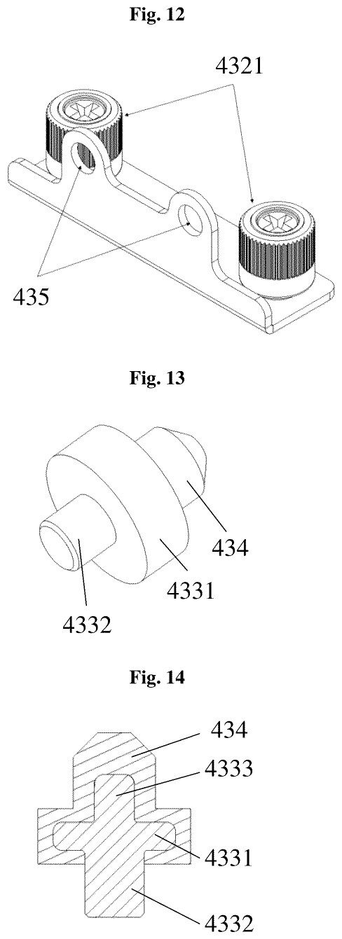

In some embodiments, referring to FIGS. 11-12, the heat dissipation mounting bracket 43 includes an extension member 431 and a heat dissipation limiting member 432, and a heat dissipation space for accommodating the heat dissipation member 42 is disposed between the heat dissipation limiting member 432 and the extension member 431. The extension member 431 is connected to the processor body 41, and the heat dissipation limiting member 432 is detachably connected to the extension member 431. An edge, away from the processor body 41, of the extension member 431 is provided with a support edge 4311, and the support edge 4311 is fittingly connected to the support portion in the frame body 1. Specifically, the extension member 431 includes a bottom plate and a side plate, and the extension member 431 may be either of an integrated structure or a pre-assembled structure of the bottom plate and side plate. The heat dissipation member 42 is detachably installed on the extension member 431, and the extension member 431 is detachably installed on the processor body 41. Specifically, the extension member 431 is provided with an assembly hole 4312 and is fixed to the processor body 41 through screws. The heat dissipation limiting member 432 is configured to fix the heat dissipation member 42. The side plate is located on one side of the bottom plate, and the heat dissipation limiting member 432 is located in a middle portion of the bottom plate. By installing the heat dissipation limiting member 432 in the middle portion of the bottom plate, a certain space may be reserved for the bottom plate for cooperative connection with the support portion. The heat dissipation space for accommodating the heat dissipation member 42 is formed between the side plate and the heat dissipation limiting member 432. The side plate is detachably connected to the processor body 41, the heat dissipation limiting member 432 is detachably connected to the bottom plate, and after installation of the heat dissipation member 42 is completed, the heat dissipation limiting member 432 is connected to the bottom plate. In an embodiment, both the side plate and the heat dissipation limiting member 432 are of a U-shaped structure, openings of the side plate and the heat dissipation limiting member 432 are disposed towards the heat dissipation member 42 for better limiting the heat dissipation member 42, meanwhile, a contact area with the bottom plate is increased, and connection is firmer. Moreover, an edge, away from the processor body 41, of the bottom plate is provided with the support edge 4311, and the support edge 4311 is fittingly connected to the support portion in the support body 1. Specifically, the heat dissipation limiting member 432 is connected to the bottom plate through a threaded fastener 4321, and the threaded fastener 4321 may be a thumb screw. The bottom plate is provided with a connection hole, and the connection hole may also be replaced with a nut. The threaded fastener 4321 penetrates through the heat dissipation limiting member 432 and then is fixed into the connection hole in the bottom plate, thereby achieving a fixed connection between the heat dissipation limiting member 432 and the bottom plate of the extension member 431. When the heat dissipation member 42 needs to be detached or replaced, the threaded fastener 4321 is reversely rotated to separate the heat dissipation limiting member 432 from the extension member 431, making it convenient to use.

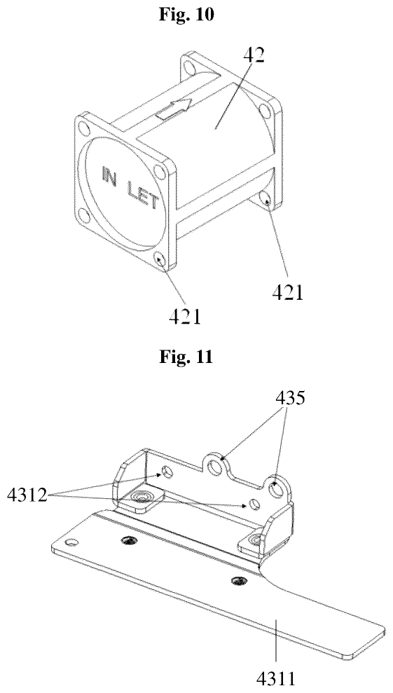

In some embodiments, referring to FIG. 10, two ends of the heat dissipation member 42 are provided with a heat dissipation fixing hole 421, and both the extension member 431 and the heat dissipation limiting member 432 are provided with a mounting bracket fixing hole 435. The heat dissipation fixing hole 421 and the mounting bracket fixing hole 435 are detachably connected through a heat dissipation fixing member 433. Specifically, the heat dissipation fixing hole 421 and the mounting bracket fixing hole 435 may be fixed through a bolt or rivet, and any method that may achieve a detachable connection between the heat dissipation fixing hole 421 and the mounting bracket fixing hole 435 through the heat dissipation fixing member 433 is acceptable. By using the detachable connection method, the heat dissipation member 42 may be installed for the required processor body 41. In other words, each processor body 41 is provided with the heat dissipation mounting bracket 43, on which the heat dissipation member 42 may be installed according to requirements. If there is no need for heat dissipation, the mounting bracket fixing hole 435 and the heat dissipation fixing member 433 may not be added.

With the foregoing arrangement, the heat dissipation limiting member 432 is designed to be fixed to the extension member 431 without tools, and the heat dissipation member 42 is assembled and fixed to the extension member 431 or the heat dissipation limiting member 432 through the heat dissipation fixing member 433. The extension member 431 is designed with the mounting bracket fixing hole 435 and the connection hole, the connection hole may fix the heat dissipation limiting member 432, and the heat dissipation limiting member 432 is provided with the thumb screw. These functions may achieve tool-free fixation of the heat dissipation member 42 to the extension member 431.

In some embodiments, referring to FIGS. 13-14, the processor integrated module 10 further includes a shock-absorbing pad 434. The heat dissipation fixing member 433 includes a fixing member body 4331, a first fixing post 4332, and a second fixing post 4333. The first fixing post 4332 is connected to the heat dissipation fixing hole 421 by interference fit. The shock-absorbing pad 434 is wrapped around the fixing member body 4331 and the second fixing post 4333, meaning that a rubber pad on an outer side of the heat dissipation fixing member 433 is partial encapsulation, and the encapsulation is achieved through in-mold two-color injection molding. A position, close the second fixing post 4333, of the shock-absorbing pad 434 is connected to the mounting bracket fixing hole 435 by interference fit. Specifically, the arrangement of the fixing member body 4331, the first fixing post 4332, and the second fixing post 4333 facilitates the interference fit connection between the heat dissipation fixing member 433 and the heat dissipation fixing hole 421 or the mounting bracket fixing hole 435. Meanwhile, in an embodiment, the fixing member body 4331 is circular, thereby ensuring the firmness of the position of the shock-absorbing pad 434. Specifically, one end, away from the first fixing post 4332, of the shock-absorbing pad 434 is in a frustum shape, facilitating insertion into the mounting bracket fixing hole 435. In an embodiment, the shock-absorbing pad 434 is a rubber pad. The arrangement of the shock-absorbing pad 434 may further reduce the vibration impact generated by the heat dissipation member 42, thereby reducing noise.

In some embodiments, the processor integrated module 10 further includes: a position detecting member, an alarm member, a power mechanism, and a controller are further included. The position detecting member is configured for detecting whether the processor assembly 4 is installed in the chamber in place. The position detecting member may be a sensor or a spring pin, or any structure capable of detecting position and reminding installation in place. ; an alarm member, the alarm member is connected to the position detecting member, and is configured for emitting an alarm signal after the processor assembly 4 is installed in place, and the alarm signal may be an optical signal or an acoustic signal; a power mechanism, the power mechanism is configured for driving the movement of the first limiting member 2 and the second limiting member 3. The power mechanism may be a structure such as a motor and an air cylinder installed on the first limiting member 2 and/or the second limiting member 3; a controller, the controller is connected to the alarm member, and is configured for controlling the rotation of the first limiting member 2 to fit against the first side frame 12 and the rotation of the second limiting member 3 to fit against the second side frame 13 after receiving the alarm signal, thereby achieving automatic control of the first limiting member 2 or the second limiting member 3. The foregoing arrangement may be applied to the fully automatic installation of the processor integrated module 10, thereby achieving automatic assembly.

According to the processor integrated module 10 provided in the present disclosure, compared with processor fans in the related art, some related processor fans merely add a processor fan and a fixing bracket at an air intake end of the processor, which increases a weight of the processor assembly 4 without achieving reliable fixation at the air intake end of the processor, resulting in poor processor fixation reliability and affecting processor performance. In the processor integrated module 10 of the present disclosure, the heat dissipation member 42 is compatible with the processor extension member 431 in the related art, not affecting reliable fixation of the original processor. Compared with the processor fans in the related art, some processor fans in the related art are directly integrated within the processor, but the method fails to predict the actual heat dissipation impact of the processor within the system in advance, that is, some systems have good heat dissipation configuration and may not require a dedicated processor cooling fan, leading to unnecessary cost increases caused by the processor fans. In the processor integrated module 10 of the present disclosure, the heat dissipation member 42 is a detachable and optional accessory that may be added or removed according to system design requirements, resulting in better cost-effectiveness. Compared with a fan fixation method in the related art, where the shock-absorbing pad 434 and the heat dissipation fixing member 433 are typically separate components, causing the problem of the rubber pad easily detaching during installation. In the processor integrated module 10 of the present disclosure, two-color injection molding is adopted for the shock-absorbing pad 434, which ensures the strength of the heat dissipation fixing member 433 while maintaining a good vibration damping effect of the shock-absorbing pad 434. Additionally, manual installation costs may be reduced, and the problem of the shock-absorbing pad 434 easily detaching during the installation of the heat dissipation member 42 is solved.

In addition to the processor integrated module 10 mentioned above, the present disclosure also provides a server that includes the foregoing processor integrated module 10. For structures of other parts of the server, please refer to the related art about the server, and details are not provided herein.

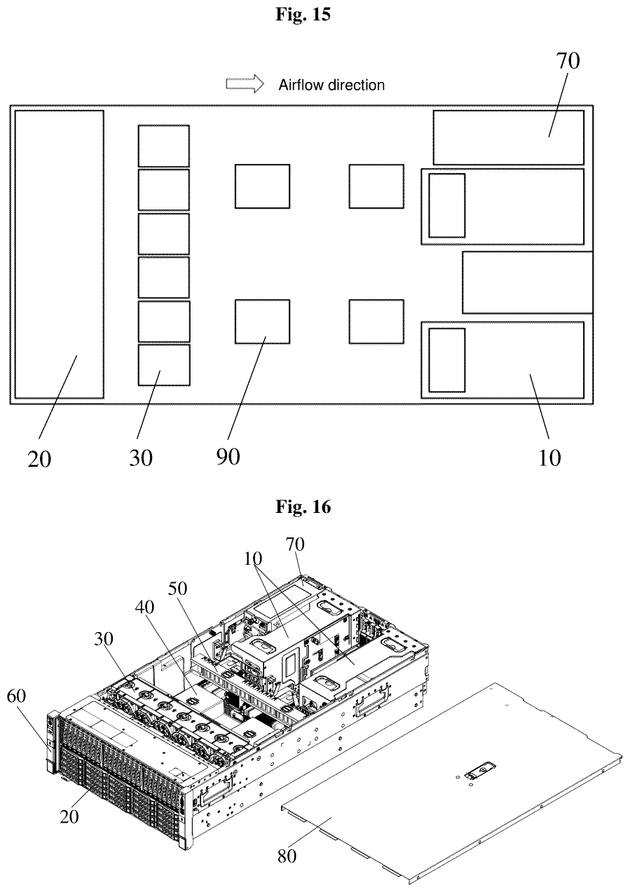

Referring to FIGS. 15-16, the server further includes a chassis base 60, a hard disk module 20, a fan module 30, a CPU 90, an air guide hood, a power module 70, and a chassis upper cover 80. The hard disk module 20, the fan module 30, the air guide hood, the power module 70, and the chassis upper cover 80 are all installed on the chassis base 60. The processor integrated module 10 is installed on the air guide hood. Specifically, the air guide hood includes a front air guide hood 40 and a rear air guide hood 50. The chassis base 60 is primarily configured to integrate server-related components to achieve server-related functions. From front to back, the chassis base 60 is sequentially provided with the hard disk module 20, the fan module 30, the front air guide hood 40, the rear air guide hood 50, the processor integrated module 10, and the power module 70. The fan module 30 is configured for dissipating heat for the CPU 90. The hard disk module 20 is typically a mechanical hard disk. As shown in FIG. 17, the processor integrated module 10 is fixed to the rear air guide hood 50 through a third locking member 19.

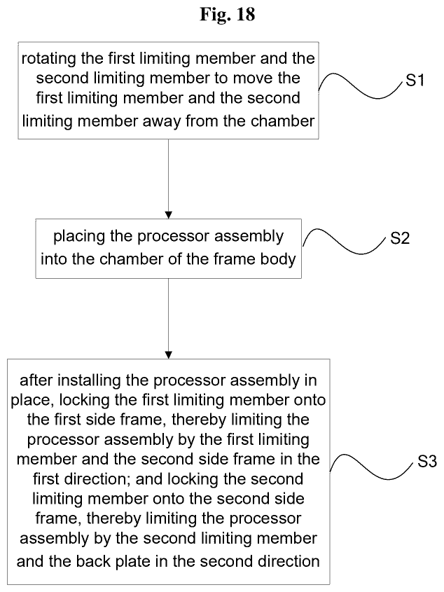

In addition to the processor integrated module 10 and the server mentioned above, referring to FIG. 18, the present disclosure further provides an assembly method for a processor integrated module, including the following steps: rotating a first limiting member 2 and a second limiting member 3 to move the first limiting member 2 and the second limiting member 3 away from a chamber; placing a processor assembly 4 into the chamber of a frame body 1; after installing the processor assembly 4 in place, locking the first limiting member 2 onto a first side frame 12, thereby limiting the processor assembly 4 by the first limiting member 2 and a second side frame 13 in the first direction; and locking the second limiting member 3 onto the second side frame 13, thereby limiting the processor assembly 4 by the second limiting member 3 and a back plate 11 in the second direction.

According to the assembly method for a processor integrated module, the first limiting member 2 and the second limiting member 3 are rotated to make way for the processor assembly 4, thereby facilitating the arrangement of the processor assembly 4 into the chamber of the frame body 1. After the processor assembly 4 is installed in place, the first limiting member 2 is rotated to fasten one end of the processor assembly 4 in the first direction, thereby limiting the processor assembly 4 in the first direction. The second limiting member 3 is rotated to fasten one side of the processor assembly 4 in the second direction, thereby limiting the processor assembly 4 in the second direction. Subsequently, the first limiting member 2 is locked onto the first side frame 12, and the second limiting member 3 is locked onto the second side frame 13, thereby completing the assembly process of the processor integrated module 10, achieving multi-angle fixation of the processor assembly 4, thus effectively reducing the noise and vibration impact caused by the arrangement of the heat dissipation member 42 on the processor assembly 4, and minimizing the impact on use experience of the user while meeting the heat dissipation requirements of the processor assembly 4.

Specifically, in an embodiment, the assembly method for a processor integrated module includes: fixing the riser card 5 to the frame body through screws; fixing the heat dissipation mounting bracket 43 to one end of a processor body 41 through screws, and then installing each heat dissipation fixing member 433 onto the heat dissipation member 42 and the heat dissipation mounting bracket 43 through interference fit, where two heat dissipation fixing members 433 are disposed on a left position and a right position of a lower portion of one side of the heat dissipation member 42, then, the additional two heat dissipation fixing members 433 are installed on the other side of the heat dissipation member 42, and after heat dissipation limiting members 432 are assembled with the heat dissipation fixing members 433, the heat dissipation limiting members 432 are fixed to a bottom plate through the threaded fastener 4321; rotatably opening the first limiting member 2 and the second limiting member 3, then arranging the processor assembly 4 into the chamber along the first slideway 121 and the second slideway 131, then fixedly pressing the first limiting member 2 against one side of the processor assembly 4, and rotating the second limiting member 3 to lock and fix the other side of the processor assembly 4; and arranging the processor integrated module 10 onto the chassis base 60, fixing the processor integrated module 10 to the rear air guide hood 50 through the third locking member 19, and then closing the chassis top cover 80.

By adding the heat dissipation member 42 dedicated to the processor body 41 on the processor body 41, the problem about heat dissipation of the processor body 41, such as a GPU card is solved in a more targeted manner, the increase in the overall rotational speed of the system fan is avoided, which helps to avoid the additional costs associated with more noise reduction measures that are required to mitigate the impact of noise on hard disk transmission performance after the rotational speed of the system fan is increased, and also helps to avoid the impact of the added noise from the fan module 30 on the noise environment for operation and maintenance personnel, thereby preserving user experience.

The various embodiments in the specification are described in a progressive manner, with each embodiment highlighting the differences from other embodiments. The identical or similar parts between the various embodiments may be cross-referenced to each other.

The processor integrated module, the server, and the assembly method for a processor integrated module provided by the present disclosure are described in detail above. The specific examples are applied in this specification to illustrate the principles and embodiments of the present disclosure. The descriptions of the foregoing embodiments are merely intended to facilitate the understanding of the method and core ideas of the present disclosure. It should be noted that those of ordinary skill in the art may also make a plurality of improvements and modifications on the present disclosure without departing from the principle of the present disclosure, and these improvements and modifications shall fall within the scope of protection of the present disclosure.

1. A processor integrated module, comprising:
a frame body, wherein the frame body comprises a back plate, and a first side frame and a second side frame which are opposite to each other, the back plate, the first side frame, and the second side frame enclose to form a chamber, a support portion for accommodating a processor assembly is disposed in the chamber of the frame body, and the processor assembly is provided with a heat dissipation member;
a first limiting member, wherein the first limiting member is rotatably installed on the frame body, and the first limiting member and the second side frame limit the processor assembly in a first direction; and
a second limiting member, wherein the second limiting member is rotatably installed on the frame body, and the second limiting member and the back plate limit the processor assembly in a second direction, and the second direction is perpendicular to the first direction and parallel to a direction in which the processor assembly enters and exits the chamber;
the support portion comprises a first slideway located on an inner wall of the first side frame and a second slideway located on an inner wall of the second side frame, a plurality of first slideways and a plurality of second slideways are provided, the first slideway is arranged parallel to the second slideway, and two ends of the processor assembly in the first direction slide along the first slideway and the second slideway respectively to enter or exit the chamber.

2. The processor integrated module according to claim 1, wherein the processor integrated module further comprises:
a first locking member, wherein the first locking member is configured for locking or unlocking the first limiting member and the first side frame, one side of the first limiting member is hingedly connected to the first side frame or the back plate, the other side thereof is connected to the first locking member, the first locking member is movably installed on the first side frame, and in response to the first locking member being unlocked, the first limiting member swings relative to the first side frame; and
a second locking member, wherein the second locking member is configured for locking or unlocking the second limiting member and the second side frame, one side of the second limiting member is hingedly connected to the second side frame or the back plate, the other side thereof is connected to the second locking member, the second locking member is movably installed on the second side frame, and in response to the second locking member being unlocked, the second limiting member swings relative to the second side frame.

3. The processor integrated module according to claim 2, wherein the first locking member is a threaded fastener the first side frame is provided with a threaded hole, and the threaded fastener is assembled into the threaded hole and is in fastened connection; and
the second locking member comprises a slider and a locking edge the locking edge is located at a movable end of the second limiting member, the slider is disposed on the second side frame, and in response to the second limiting member tightly fitting against the second side frame, the slider slides to the locking edge for snap fit to lock a position of the second limiting member.

4. The processor integrated module according to claim 1, wherein the second limiting member is provided with an elastic structure, and in response to the second limiting member being opened and the processor assembly being completely installed, the elastic structure drives the second limiting member to be kept in a locked state.

5. (canceled)

6. The processor integrated module according to claim 1, wherein a movable end of the first limiting member is further provided with a limiting edge, and the limiting edge is internally provided with a limiting slot the limiting slot is configured for accommodating a corner of the processor assembly, and limits the processor assembly in the first direction and the second direction.

7. The processor integrated module according to claim 6, wherein a notch portion is disposed on one side, away from the back plate, of the first side frame, and a rotation of the first limiting member moves the limiting edge to the notch portion and the limiting slot in the limiting edge communicates with the first slideway.

8. The processor integrated module according to claim 1, wherein the processor integrated module further comprises:
at least two handles for gripping, wherein the frame body is provided with grooves, the at least two handles are arc-shaped with rotating shafts at two ends, and the at least two handles are rotatably installed in the grooves through the rotating shafts and are able to extend out of the grooves; and/or
a third locking member, wherein a locking edge is disposed on one side, away from the first side frame, of the first limiting member, the locking edge is suspended over a surface of an air guide hood of a server or inserted into a housing of the air guide hood, and the third locking member is disposed on the locking edge and is in fastened connection to the air guide hood.

9. The processor integrated module according to claim 1, wherein the processor integrated module further comprises:
a first rotating shaft, wherein one side of the first limiting member is rotatably connected to the first rotating shaft, the other side thereof rotates relative to the first rotating shaft and opens towards an outer side of the first side frame, and one side, away from the first rotating shaft, of the first limiting member is detachably connected to the first side frame; and
a second rotating shaft, wherein one side of the second limiting member is rotatably connected to the second rotating shaft, the other side thereof rotates relative to the second rotating shaft and opens towards an outer side of the second side frame, and one side, away from the second rotating shaft, of the second limiting member is detachably connected to the second side frame;
the frame body further comprises a top plate perpendicular to the back plate, the first side frame is connected to one end of the top plate and one end of the back plate, the second side frame is connected to the other end of the top plate and the other end of the back plate; the first rotating shaft is located on a connecting edge between the first side frame and the top plate, or on a connecting edge between the first side frame and the back plate, an extension direction of the first rotating shaft is parallel to a plane where the first side frame is located; the second rotating shaft is located at a corner, away from the top plate and the back plate, of the second side frame, and an extension direction of the second rotating shaft is perpendicular to a plane where the second side frame is located; and
the first rotating shaft is further provided with a first angle limiting portion configured for limiting a maximum rotation angle of the first limiting member, and the second rotating shaft is further provided with a second angle limiting portion configured for limiting a maximum rotation angle of the second limiting member.

10. (canceled)

11. The processor integrated module according to claim 8, wherein a plurality of reinforcing ribs are disposed between the locking edge and the first limiting member, and a ventilation channel is disposed between adjacent reinforcing ribs of the plurality of reinforcing ribs, and allows air to flow from an outer side of the first limiting member into the chamber of the frame body.

12. The processor integrated module according to claim 1, wherein
the first limiting member is provided with a first magnetic locking member, and the first side frame is provided with a first magnetic member, and the first magnetic member attracts the first magnetic locking member; and
the second limiting member is provided with a second magnetic locking member, and the second side frame is provided with a second magnetic member, and the second magnetic member attracts the second magnetic locking member.

13. The processor integrated module according to claim 1, wherein the processor assembly comprises:
a processor body;
a heat dissipation member, wherein the heat dissipation member is configured for dissipating heat for the processor body; and
a heat dissipation mounting bracket, wherein the heat dissipation mounting bracket is disposed at one end of the processor body in the first direction, and the heat dissipation member is detachably disposed on the heat dissipation mounting bracket.

14. The processor integrated module according to claim 13, wherein the heat dissipation mounting bracket is installed at a first end of the processor body in the first direction, and the heat dissipation mounting bracket is connected to the first side frame, a second end of the processor body in the first direction is connected to the second side frame, and the first side frame is provided with a plurality of ventilation slots.

15. The processor integrated module according to claim 14, wherein the heat dissipation mounting bracket comprises an extension member and a heat dissipation limiting member and a heat dissipation space for accommodating the heat dissipation member is disposed between the heat dissipation limiting member and the extension member the extension member is connected to the processor body, and the heat dissipation limiting member is detachably connected to the extension member and an edge, away from the processor body, of the extension member is provided with a support edge and the support edge is fittingly connected to a support portion in the frame body.

16. The processor integrated module according to claim 15, wherein two ends of the heat dissipation member are provided with a heat dissipation fixing hole both the extension member and the heat dissipation limiting member are provided with a mounting bracket fixing hole and the heat dissipation fixing hole and the mounting bracket fixing hole are detachably connected through a heat dissipation fixing member.

17. The processor integrated module according to claim 16, wherein the processor integrated module further comprises a shock-absorbing pad the heat dissipation fixing member comprises a fixing member body a first fixing post and a second fixing post the first fixing post is connected to the heat dissipation fixing hole by interference fit, the shock-absorbing pad is wrapped around the fixing member body and the second fixing post and a position, close the second fixing post of the shock-absorbing pad is connected to the mounting bracket fixing hole by interference fit.

18. The processor integrated module according to claim 15, wherein the extension member comprises a bottom plate and a side plate, the bottom plate is located on one side of the bottom plate, the side plate is detachably connected to the processor body, and the heat dissipation limiting member is located in a middle portion of the bottom plate and is detachably connected to the bottom plate.

19. The processor integrated module according to claim 18, wherein both the side plate and the heat dissipation limiting member are of a U-shaped structure, and openings of the side plate and the heat dissipation limiting member are arranged towards the heat dissipation member; and
an edge, away from the processor body, of the bottom plate is provided with the support edge and the support edge is fittingly connected to the support portion in the frame body.

20. The processor integrated module according to claim 1, wherein the processor integrated module further comprises:
a position detecting member, wherein the position detecting member is configured for detecting whether the processor assembly is installed in the chamber in place;
an alarm member, wherein the alarm member is connected to the position detecting member, and is configured for emitting an alarm signal in response to the processor assembly being installed in place;
a power mechanism, wherein the power mechanism is configured for driving a movement of the first limiting member and the second limiting member; and
a controller, wherein the controller is connected to the alarm member, and is configured for controlling a rotation of the first limiting member to fit against the first side frame and a rotation of the second limiting member to fit against the second side frame in response to receiving the alarm signal.

21. A server, comprising a processor integrated module, and the processor integrated module is the processor integrated module according to claim 1.

22. An assembly method for a processor integrated module, configured for assembling the processor integrated module according to claim 1, comprising the following steps:
rotating the first limiting member and the second limiting member to move the first limiting member and the second limiting member away from the chamber;
placing the processor assembly into the chamber of the frame body; and
after installing the processor assembly in place, locking the first limiting member onto the first side frame, thereby limiting the processor assembly by the first limiting member and the second side frame in the first direction; and locking the second limiting member onto the second side frame, thereby limiting the processor assembly by the second limiting member and the back plate in the second direction.
